(19) United States
(12) Patent Application Publication
(10) Pub. No.: US 2026/0235527 A1
(43) Pub. Date: Aug. 13, 2026

(54) COMBINED LASER SOURCES FOR SAMPLE CHARACTERIZATION

(71) Applicant: KLA Corporation, Milpitas, CA (US)

(72) Inventors: Guoheng Zhao, Palo Alto, CA (US); Guowu Zheng, San Jose, CA (US); Serguei Likhanski, San Jose, CA (US); Daniel Ivanov Kavaldjiev, San Jose, CA (US); Stephen Biellak, Sunnyvale, CA (US); Zhiwei Xu, Sunnyvale, CA (US); Christian Wolters, San Jose, CA (US); Jijen Vazhaeparambil, Saratoga, CA (US)

(21) Appl. No.: 19/532,715

(22) Filed: Feb. 6, 2026

Related U.S. Application Data
(60) Provisional application No. 63/758,331, filed on Feb. 13, 2025.

(51) Int. Cl. G01N 21/88; G01N 21/17

(52) U.S. Cl. CPC G01N 21/8806; G01N 2021/1765; G01N 2021/8825; G01N 2021/8848; G01N 2201/06113; G01N 2201/0631; G01N 2201/0697

(57) ABSTRACT

A light source may include multiple lasers, wherein each laser is configured to generate a pulsed laser beam at a pulse repetition rate. The light source may include a beam combining assembly including one or more beam combining optics configured to direct the pulsed laser beams from the lasers along a common beam path to form a combined laser beam. All pulses in the combined laser beam may have a common polarization state. The light source may include a timing controller communicatively coupled to the lasers. The timing controller may be configured to synchronize pulse generation of each laser such that the combined laser beam has a combined pulse repetition rate greater than the pulse repetition rate of any of the lasers.

### CROSS-REFERENCE TO RELATED APPLICATIONS

The present application claims the benefit under 35 U.S.C. § 119 (e) of U.S. Provisional Application No. 63/758,331 filed on Feb. 13, 2025, which is incorporated herein by reference in the entirety.

### TECHNICAL FIELD

The present disclosure relates generally to illumination sources for sample characterization and, more particularly, to combining multiple lasers to generate high repetition rate pulsed illumination for sample inspection, metrology, and characterization systems.

### BACKGROUND

Optical sample characterization systems, including inspection and metrology systems, are used to detect defects and measure features on samples such as semiconductor wafers, photomasks, and other substrates during manufacturing processes. Shorter wavelengths and higher power lasers have been primary drivers for improving detection sensitivity and measurement precision in such systems. As feature sizes on semiconductor devices continue to shrink, there is an increasing demand for characterization systems operating at shorter wavelengths in the deep ultraviolet (DUV) and vacuum ultraviolet (VUV) ranges. Among the limited options for high power lasers below 200 nm, 193 nm excimer lasers represent a mature technology with relatively high power output. However, commercially available 193 nm excimer lasers typically operate at low pulse repetition rates, generally in the range of 100 Hz to 6 kHz. While high repetition rate excimer lasers developed for lithography applications can achieve pulse rates up to 6 kHz, these lasers are prohibitively expensive and have large footprints that make them unsuitable for sample characterization applications. Solid-state lasers at 193 nm offer an alternative but suffer from low output power and high cost due to low conversion efficiency.

Prior approaches to increasing laser pulse repetition rates have relied on splitting a laser beam into multiple beams, delaying each split beam by a distance longer than the distance the pulse travels within one pulse width, and recombining the delayed beams. Some approaches use optical cavities to recirculate laser beams to extend delay length within a limited footprint. However, these methods face practical limitations when applied to low repetition rate lasers. The delay length for uniform pulse rate multiplication is inversely proportional to the laser repetition rate, requiring approximately 150 km of delay to double a 1 kHz laser pulse rate to 2 KHz. Such delay lengths are impractical to implement. Additionally, long delay paths require multiple mirror reflections, and the cumulative reflection losses at DUV wavelengths quickly degrade efficiency. Some beam splitting and recombining methods also increase the beam etendue, which reduces illumination efficiency for dark field imaging systems. Therefore, it is desirable to provide systems and methods for curing the above deficiencies.

### SUMMARY

In embodiments, a light source is provided. The light source may include a plurality of lasers, where each laser of the plurality of lasers is configured to generate a pulsed laser beam at a pulse repetition rate. The light source may include a beam combining assembly including one or more beam combining optics configured to direct the pulsed laser beams from the plurality of lasers along a common beam path to form a combined laser beam. All pulses in the combined laser beam may have a common polarization state. The light source may include a timing controller communicatively coupled to the plurality of lasers. The timing controller may be configured to synchronize pulse generation of each laser of the plurality of lasers such that the combined laser beam has a combined pulse repetition rate greater than the pulse repetition rate of any of the plurality of lasers.

In embodiments, the beam combining assembly may include one or more polarizing beam splitters configured to combine the pulsed laser beams from the plurality of lasers into a colinear beam having orthogonal polarization states separated in a time domain. The beam combining assembly may include a polarization modulator in the common beam path. The polarization modulator may be configured to selectively rotate a polarization state of a subset of pulses in the combined laser beam by modulating a polarization rotation applied to the pulses in synchronization with the pulse generation such that all pulses in the combined laser beam have the common polarization state.

In embodiments, the polarization modulator may include an electro-optic modulator including a Pockels cell.

In embodiments, the polarization modulator may include one or more half waveplates arranged on a rotating mount. The rotating mount may be configured to selectively insert the one or more half waveplates into the common beam path in synchronization with the pulse generation.

In embodiments, the timing controller may be communicatively coupled to the polarization modulator and configured to synchronize operation of the polarization modulator with the pulse generation of each laser of the plurality of lasers.

In embodiments, the beam combining assembly may include a rotating patterned mirror having alternating transparent regions and opaque regions. The rotating patterned mirror may include a glass substrate having a patterned mirror coating defining the opaque regions. Rotation of the rotating patterned mirror may be synchronized with the pulse generation of each laser of the plurality of lasers to alternately reflect and transmit the pulsed laser beams from the plurality of lasers into the combined laser beam.

In embodiments, the timing controller may be configured to synchronize the pulse generation such that laser pulses in the combined laser beam are distributed uniformly in a time domain.

In embodiments, the light source may further include a beam homogenizer configured to homogenize at least one pulsed laser beam of the pulsed laser beams from the plurality of lasers.

In embodiments, the beam homogenizer may include a light pipe.

In embodiments, the light source may further include a polarization recovery assembly configured to receive a depolarized beam from the beam homogenizer and output a polarized beam. The polarization recovery assembly may include a first polarizing beam splitter configured to separate the depolarized beam into a first polarization component and a second polarization component. The polarization recovery assembly may include a delay path configured to delay the second polarization component relative to the first polarization component. The polarization recovery assembly may include a second polarizing beam splitter configured to recombine the first polarization component and the delayed second polarization component into a recombined beam. The polarization recovery assembly may include a polarization rotator configured to rotate a polarization state of one of the first polarization component or the delayed second polarization component such that the recombined beam is linearly polarized.

In embodiments, the recombined beam may include pulse bursts at the combined repetition rate. Each pulse burst may include a first sub-pulse from the first polarization component and a second sub-pulse from the delayed second polarization component.

In embodiments, the one or more beam combining optics may include a light pipe configured to receive the pulsed laser beams from the plurality of lasers.

In embodiments, the plurality of lasers may include a plurality of laser cavities sharing at least one of a common housing, a common gas supply, or a common power supply.

In embodiments, the plurality of lasers may include excimer lasers.

In embodiments, a sample characterization system is provided. The sample characterization system may include a light source. The light source may include a plurality of lasers, where each laser of the plurality of lasers is configured to generate a pulsed laser beam at a pulse repetition rate. The light source may include a beam combining assembly including one or more beam combining optics configured to direct the pulsed laser beams from the plurality of lasers along a common beam path to form a combined laser beam. All pulses in the combined laser beam may have a common polarization state. The light source may include a timing controller communicatively coupled to the plurality of lasers. The timing controller may be configured to synchronize pulse generation of each laser of the plurality of lasers such that the combined laser beam has a combined pulse repetition rate greater than the pulse repetition rate of any of the plurality of lasers. The sample characterization system may include illumination optics configured to direct the combined laser beam onto a sample. The sample characterization system may include collection optics configured to collect light from the sample. The sample characterization system may include a time delay integration (TDI) sensor configured to receive the collected light. The TDI sensor may be configured to operate at a line rate synchronized with motion of the sample such that a number of TDI integration lines covers a distance the sample travels between consecutive laser pulses in the combined laser beam.

In embodiments, the sample characterization system may further include a pulse stretcher configured to temporally stretch pulses in the combined laser beam such that each stretched pulse covers multiple TDI integration lines along a scan direction.

In embodiments, the pulse stretcher may be configured to stretch each pulse to a duration between 0.1 microseconds and 1 microsecond.

In embodiments, an illumination beam size of the combined laser beam on the sample may cover a total number of TDI integration lines in both horizontal and vertical directions.

In embodiments, the sample characterization system may further include a controller including one or more processors configured to generate sample measurements based on data from the TDI sensor.

In embodiments, the sample characterization system may be an inspection system and the sample measurements may include at least one of identification of defects on the sample or characterization of defects on the sample.

In embodiments, the plurality of lasers may include excimer lasers.

In embodiments, a method is provided. The method may include generating a plurality of pulsed laser beams from a plurality of lasers, where each laser of the plurality of lasers generates a pulsed laser beam at a pulse repetition rate. The method may include combining the plurality of pulsed laser beams along a common beam path to form a combined laser beam having a combined pulse repetition rate greater than the pulse repetition rate of each laser of the plurality of lasers. All pulses in the combined laser beam may have a common polarization state. The method may include synchronizing pulse generation of each laser of the plurality of lasers such that the combined laser beam has the combined pulse repetition rate.

In embodiments, synchronizing the pulse generation may include distributing laser pulses in the combined laser beam uniformly in a time domain.

In embodiments, combining the plurality of pulsed laser beams may include directing the plurality of pulsed laser beams through one or more polarizing beam splitters to form a colinear beam having orthogonal polarization states separated in the time domain. Combining the plurality of pulsed laser beams may include selectively rotating a polarization state of a subset of the laser pulses in synchronization with the pulse generation such that all pulses in the combined laser beam have the common polarization state.

In embodiments, combining the plurality of pulsed laser beams may include directing the plurality of pulsed laser beams onto a rotating patterned mirror having alternating transparent regions and opaque regions. Rotation of the rotating patterned mirror may be synchronized with the pulse generation to alternately reflect and transmit the pulsed laser beams into the combined laser beam.

In embodiments, the method may further include homogenizing at least one pulsed laser beam of the plurality of pulsed laser beams.

In embodiments, the method may further include recovering polarization of a depolarized beam from the homogenizing by separating the depolarized beam into a first polarization component and a second polarization component, delaying the second polarization component relative to the first polarization component, recombining the first polarization component and the delayed second polarization component into a recombined beam, and rotating a polarization state of one of the first polarization component or the delayed second polarization component such that the recombined beam is linearly polarized.

In embodiments, the method may further include temporally stretching pulses in the combined laser beam.

In embodiments, the method may further include directing the combined laser beam onto a sample, collecting light from the sample, receiving the collected light at a TDI sensor operating at a line rate synchronized with motion of the sample, and generating one or more measurements based on data from the TDI sensor.

In embodiments, generating the one or more measurements may include at least one of identifying defects on the sample or characterizing defects on the sample.

In embodiments, the plurality of lasers may include excimer lasers.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIG. 1A is a block diagram of a light source for generating a combined pulsed laser beam, in accordance with one or more embodiments of the present disclosure.

FIG. 1B is a block diagram of a light source with multiple excimer lasers formed as multiple laser cavities, in accordance with one or more embodiments of the present disclosure.

FIG. 2A is a schematic diagram of a beam combining assembly for combining pulsed laser beams from multiple excimer lasers using a polarizing beamsplitter and a polarization modulator, in accordance with one or more embodiments of the present disclosure.

FIG. 2B is a timing diagram depicting the operation of a polarization modulator relative to pulses in pulsed laser beams, in accordance with one or more embodiments of the present disclosure.

FIG. 3A is a schematic diagram of a beam combining assembly for combining three pulsed laser beams using a cascaded configuration of polarizing beamsplitters and polarization modulators, in accordance with one or more embodiments of the present disclosure.

FIG. 3B is a timing diagram depicting the operation of polarization modulators relative to pulses in pulsed laser beams, in accordance with one or more embodiments of the present disclosure.

FIG. 4A is a schematic diagram of a polarization modulator utilizing half waveplates arranged on an opaque rotating mount, in accordance with one or more embodiments of the present disclosure.

FIG. 4B is a schematic diagram of a polarization modulator utilizing half waveplates arranged on a transparent rotating mount, in accordance with one or more embodiments of the present disclosure.

FIG. 5 is a schematic diagram of a beam combining assembly utilizing a rotating patterned mirror for combining pulsed laser beams from multiple excimer lasers, in accordance with one or more embodiments of the present disclosure.

FIG. 6 is a schematic diagram of a beam combining assembly utilizing a light pipe for combining pulsed laser beams from multiple excimer lasers, in accordance with one or more embodiments of the present disclosure.

FIG. 7 is a schematic diagram of a polarization recovery assembly configured to receive a depolarized beam and output a polarized beam, in accordance with one or more embodiments of the present disclosure.

FIG. 8 is a schematic diagram of a sample characterization system incorporating a light source, in accordance with one or more embodiments of the present disclosure.

FIG. 9 is a timing diagram depicting the relationship between pulse repetition rate, combined repetition rate, and TDI frame rate, in accordance with one or more embodiments of the present disclosure.

FIG. 10 is a flowchart for a method for generating a combined laser beam from a plurality of excimer lasers with synchronized pulse generation, in accordance with one or more embodiments of the present disclosure.

FIG. 11 is a flowchart for a method for sample characterization using combined excimer laser sources, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing combined laser sources for high-speed sample characterization, where multiple low repetition rate lasers are combined to generate high repetition rate pulsed illumination suitable for wafer inspection and metrology applications. In embodiments, pulsed laser beams from multiple lasers are electronically synchronized with controlled time offsets and combined along a common beam path. Additionally, polarization modulators may ensure that all pulses in the combined laser beam have a common polarization state.

The lasers may include any type of pulsed laser suitable for the application. For example, the lasers may include, but are not limited to, excimer lasers (such as 193 nm ArF excimer lasers), solid-state lasers, fiber lasers, diode-pumped lasers, or other pulsed laser sources. In some embodiments, the lasers may be implemented as separate standalone laser units, such as commercially-available laser systems, or alternatively as multiple laser cavities sharing at least one of a common housing, a common gas supply, or a common power supply, providing flexibility in system configuration ranging from integration of discrete commercial laser components to compact integrated laser systems with multiple synchronized outputs.

Beam combining may be achieved through various optical configurations. For example, polarizing beamsplitters may combine pulsed laser beams having orthogonal polarization states into a colinear beam, with the pulses from different lasers separated in the time domain. A polarization modulator positioned in the common beam path may then selectively rotate the polarization of pulses from one or more of the lasers to produce a combined laser beam in which all pulses share a common polarization state. As another example, a rotating patterned mirror having alternating transparent and opaque regions may combine pulsed laser beams by alternately reflecting and transmitting pulses from different lasers in synchronization with the pulse generation. As another example, a light pipe may receive pulsed laser beams from multiple lasers and combine them along a common beam path while also providing beam homogenization.

In some embodiments, a polarization recovery assembly may be used to efficiently utilize unpolarized light from lasers prior to beam combining. This may be suitable for, but not limited to, application incorporating a homogenizer to increase the spatial uniformity of the output of a laser, but which may also depolarize the light. Rather than discarding one polarization component, the polarization recovery assembly separates an unpolarized pulsed laser beam into orthogonal polarization components using a first polarizing beamsplitter, delays one component relative to the other via a delay path formed by mirrors, recombines the components using a second polarizing beamsplitter, and rotates the polarization of one component using an additional polarization modulator to produce a linearly polarized output. This technique converts each unpolarized pulse into a pulse burst containing two sub-pulses with a common polarization state, effectively doubling the utilization of available laser power that would otherwise be lost when polarizing unpolarized laser output.

In embodiments, a sample characterization system incorporates the combined laser source with illumination optics configured to direct the combined laser beam onto a sample, collection optics configured to collect light from the sample, and a time delay integration (TDI) sensor configured to receive the collected light. For example, the TDI sensor may operate at a line rate synchronized with motion of the sample such that a number of TDI integration lines covers a distance the sample travels between consecutive laser pulses in the combined laser beam. A pulse stretcher may temporally stretch pulses in the combined laser beam such that each stretched pulse covers multiple TDI integration lines along a scan direction. This pulse stretching reduces peak power to mitigate laser damage to optics and the sample, reduces speckle noise, and improves sensor uniformity by averaging over multiple pixels.

The combined laser approach disclosed herein may enable substantial cost reductions compared to high repetition rate lithography-grade excimer lasers while achieving comparable or superior performance for sample characterization applications. For example, combining three compact excimer lasers operating at 2 kHz may produce a 6 KHz combined pulse train at a fraction of the cost of a single 6 kHz lithography laser. The approach also extends laser tube lifetime by distributing total pulse counts evenly among multiple laser tubes, and the use of TDI sensors with stretched pulses provides improved uniformity compared to flash-on-the-fly imaging with area sensors while minimizing image blur due to arc scan paths near wafer center by controlling the stretched pulse width to integrate over only a small number of pixels in the TDI scan direction.

Some embodiments of the present disclosure are directed to a method for generating a combined laser beam from multiple lasers. The method may include generating multiple pulsed laser beams from multiple lasers, where each laser generates a pulsed laser beam at a pulse repetition rate. The method may further include combining the pulsed laser beams along a common beam path to form a combined laser beam having a combined pulse repetition rate greater than the pulse repetition rate of each laser, wherein all pulses in the combined laser beam have a common polarization state. The method may also include synchronizing pulse generation of each laser such that laser pulses in the combined laser beam are distributed uniformly in a time domain. In some aspects, the method may include temporally stretching pulses in the combined laser beam, directing the combined laser beam onto a sample, collecting light from the sample, receiving the collected light at a time delay integration sensor operating at a line rate synchronized with motion of the sample, and generating one or more measurements based on data from the sensor.

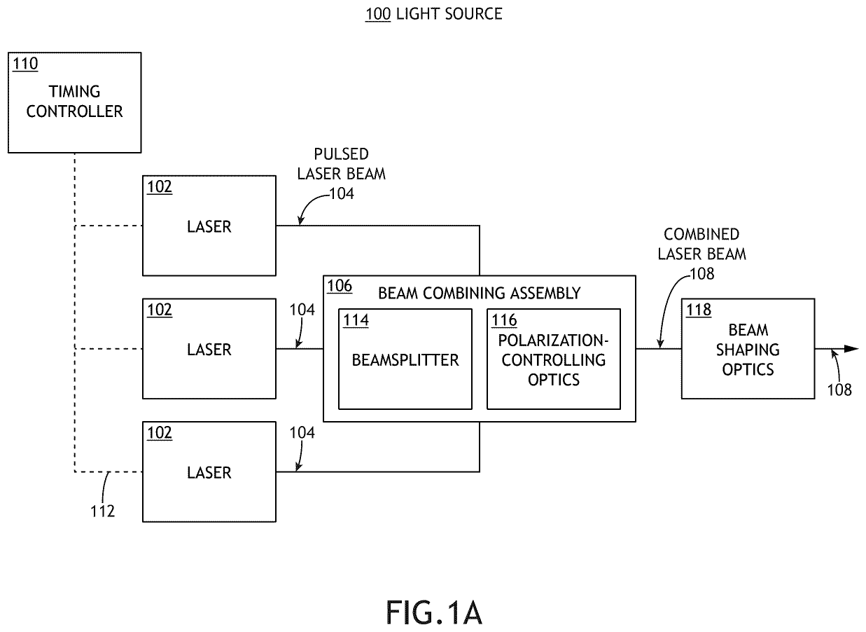

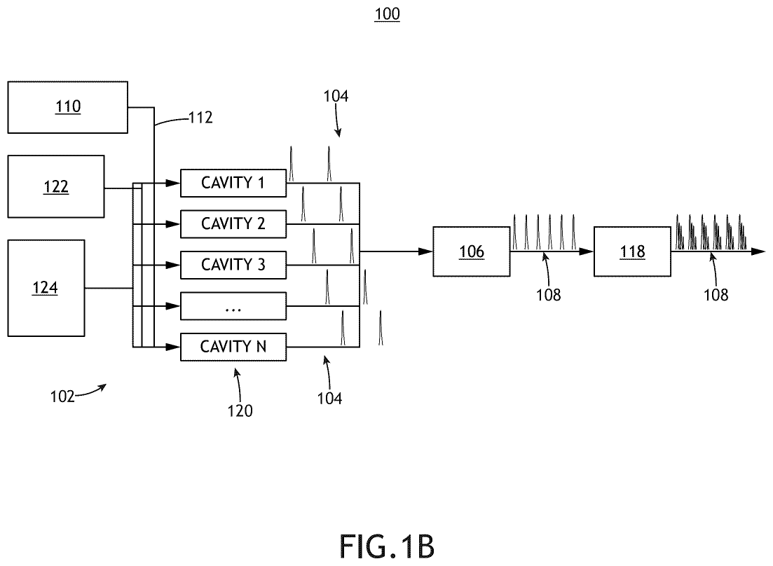

Referring now to FIGS. 1A-10, systems and methods providing high-repetition rate laser light are described, in accordance with one or more embodiments of the present disclosure.

FIG. 1A is a block diagram of a light source 100 for generating a combined pulsed laser beam, in accordance with one or more embodiments of the present disclosure.

In embodiments, the light source 100 includes multiple lasers 102, each configured to generate a pulsed laser beam 104 at a common pulse repetition rate. The lasers 102 may include any type of pulsed laser suitable for the application. For example, the lasers 102 may include, but are not limited to, excimer lasers (such as 193 nm ArF excimer lasers), solid-state lasers, fiber lasers, diode-pumped lasers, or other pulsed laser sources. A beam combining assembly 106 may receive the pulsed laser beams 104 from the lasers 102 and directs the pulsed laser beams 104 along a common beam path to form a combined laser beam 108. The beam combining assembly 106 may also manipulate the polarization states of any of the combined pulsed laser beams 104 as necessary to provide that all pulses in the combined laser beam 108 have a common polarization state. The beam combining assembly 106 may include any combination of optical components suitable for combining the pulsed laser beams 104 and optionally manipulating the polarization states of constituent pulses as necessary to ensure that all pulses in a combined laser beam 108 have a common polarization state. For example, the beam combining assembly 106 may include one or more beamsplitters, beam combiners, and/or one or more polarization modulators 116.

A timing controller 110 may be communicatively coupled to the lasers 102 and configured to synchronize pulse generation of each laser 102 such that the combined laser beam 108 has a combined pulse repetition rate greater than the pulse repetition rate of any of the lasers 102. For example, the timing controller 110 may provide timing signals 112 that provide controlled delays to interleave laser pulses in the pulsed laser beams 104 from the various lasers 102.

In some embodiments, the timing controller 110 may synchronize the lasers 102 with a time offset of 1/(N×f) between each laser, where N is the number of lasers 102 and f is the repetition rate of each individual laser 102. For example, when combining three lasers 102 each operating at 2 kHz, the timing controller 110 may synchronize the lasers 102 with a time offset of approximately 167 microseconds between successive pulses from different lasers 102, resulting in a combined pulse repetition rate of 6 KHz.

The timing controller 110 may also be communicatively coupled to the polarization modulator 116 and configured to provide additional timing signals 112 that synchronize operation of the polarization modulator 116 with the pulse generation of each laser 102, ensuring that polarization rotation is applied to the appropriate pulses to achieve the common polarization state.

In some embodiments, the light source 100 further includes beam shaping optics 118, which may manipulate any properties of the combined laser beam 108 including, but not limited to, beam shape, pulse duration, polarization, or spectral content.

In some embodiments, beam shaping optics 118 include a pulse stretcher configured to temporally stretch pulses in the combined laser beam 108. Pulse stretching may provide various benefits. For example, pulse stretching may reduce peak power of the laser pulses to reduce laser damage to optics and the wafer sample. As another example, pulse stretching may facilitate imaging based on the combined laser beam 108. For example, constituent laser pulses may be extended to cover multiple TDI integration lines along a scan direction, which may improve sensor uniformity and reduce speckle noise by averaging over multiple pixels.

A pulse stretcher may include any combination of components suitable for extending pulse durations of constituent laser pulses in the combined laser beam 108. For example, the pulse stretcher may include relay mirrors configured to extend the optical path length for pulse stretching. As another example, the pulse stretcher may include cavity mirrors configured to recirculate the laser beam for pulse stretching. As another example, the pulse stretcher may include fiber bundles configured to provide optical delay for pulse stretching. As another example, the pulse stretcher may include a beam homogenizer configured to provide both beam homogenization and pulse stretching. As another example, the pulse stretcher may include a micro lens array configured to provide pulse stretching. As another example, the pulse stretcher may include a total internal reflection (TIR) cavity configured to provide pulse stretching through multiple internal reflections. Pulse stretching and coherent reduction are generally described in U.S. patent application Ser. No. 19/532,363 filed on Feb. 6, 2026, which is incorporated herein by reference in its entirety The beam shaping optics 118 may include any combination of these pulse stretching configurations to achieve a desired stretched pulse duration and beam profile.

The lasers 102 may include any type of laser system known in the art. In some embodiments, each laser 102 comprises an excimer laser operating at a wavelength of 193 nm, which is a deep UV wavelength suitable for sample characterization applications requiring shorter wavelengths such as, but not limited to, wafer inspection.

Each laser 102 may have any suitable pulse repetition rate. For example, the lasers 102 may have, but are not limited to, pulse repetition rates in the range of 100 Hz to 6 kHz. Each laser 102 may also have any suitable output power. As an illustration, the lasers 102 may have an output powers of approximately 8 W at a 2 kHz repetition rate. However, it is to be understood that these examples are provided solely for illustrative purposes and should not be interpreted as limiting the scope of the present disclosure. In a general sense, by combining multiple lasers 102 operating at lower pulse repetition rates, the light source 100 achieves a combined pulse repetition rate suitable for high-speed sample characterization applications without requiring high-cost lithography-grade excimer lasers.

The lasers 102 in the light source 100 may have any form factor.

In some embodiments, each laser 102 may be implemented as a standalone laser unit having separate power supplies, gas lines, cooling systems, and/or housings. For example, the lasers 102 may include commercially available laser systems such as, but not limited to, excimer laser systems. In some embodiments, the lasers 102 may be implemented as a single unit with multiple laser cavities sharing at least one of a common housing, a common gas supply, or a common power supply.

FIG. 1B is a block diagram of a light source 100 with multiple lasers 102 formed as multiple laser cavities 120, in accordance with one or more embodiments of the present disclosure.

In embodiments, the lasers 102 may comprise multiple laser cavities 120 (e.g., Cavity 1, Cavity 2, Cavity 3, through Cavity N) sharing at least one of a common housing, a common gas supply 124, or a common power supply 122. As illustrated in FIG. 1B, the laser cavities 120 may share a common power supply 122 and/or a common gas supply 124. In this configuration, each of the laser cavities 120 generates a pulsed laser beam 104.

It is contemplated herein that the use of multiple laser cavities 120 may extend the lifetime of the laser system as the total number of pulses is split evenly between the multiple laser cavities 120. This configuration may also provide a more compact form factor compared to combining separate standalone excimer laser units.

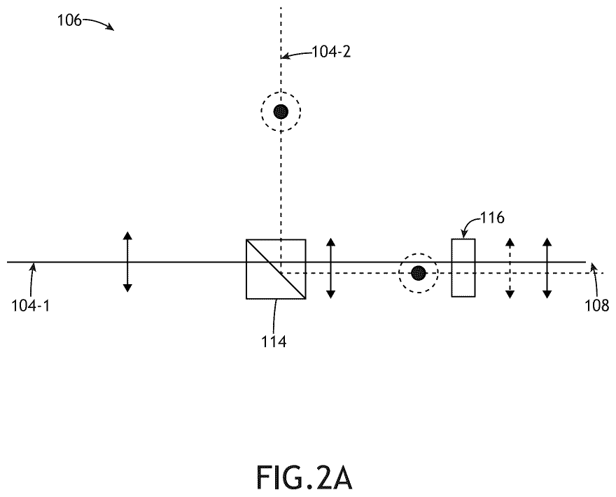

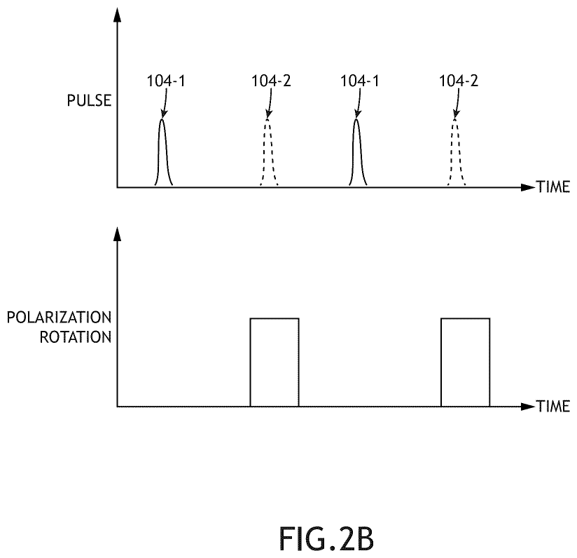

Referring now to FIGS. 2A-5, various configurations of the beam combining assembly 106 are described, in accordance with one or more embodiments of the present disclosure.

In some embodiments, the beam combining assembly 106 efficiently combines linearly polarized pulsed laser beams 104 using polarizing beamsplitters 114. For example, two pulsed laser beams 104 with orthogonal polarizations may be combined with minimal power loss using a polarizing beamsplitter 114. In these configurations, a polarization modulator 116 may selectively rotate and align the polarizations of one of the two pulsed laser beam 104 to match the other.

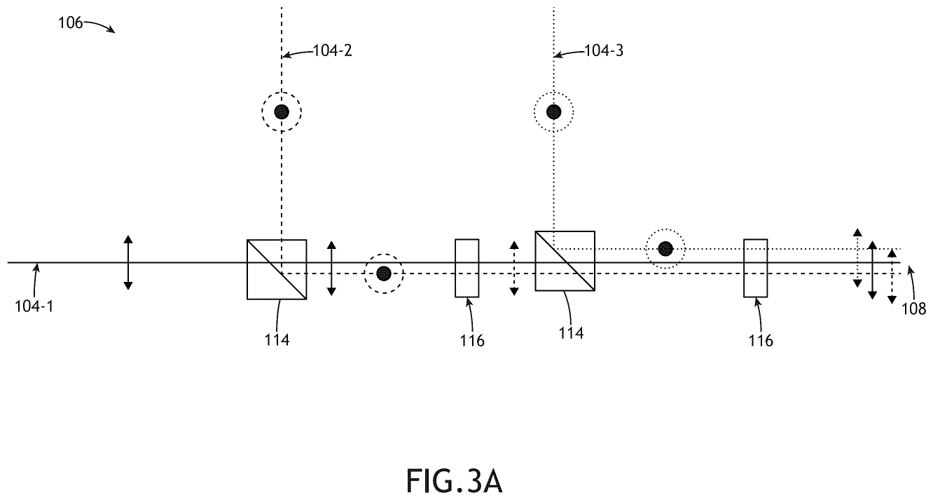

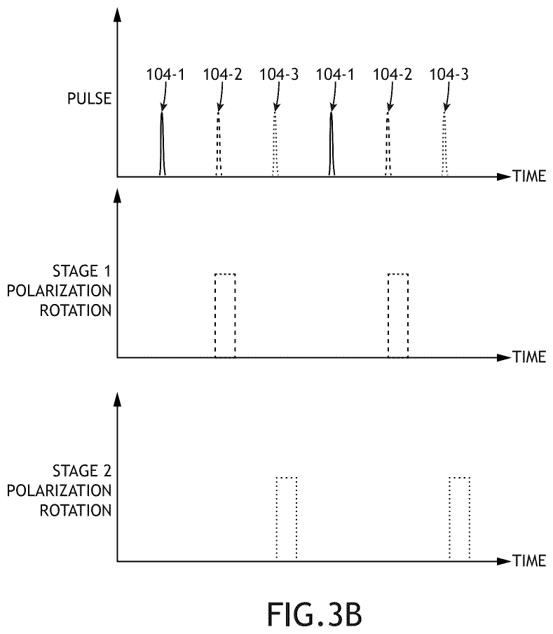

FIGS. 2A-3B depict polarization-based beam combining for two, three, or more pulsed laser beams 104.

FIG. 2A is a schematic diagram of a beam combining assembly 106 for combining pulsed laser beams from multiple lasers 102 using a polarizing beamsplitter 114 and a polarization modulator 116, in accordance with one or more embodiments of the present disclosure.

Referring to FIG. 2A, the beam combining assembly 106 receives a first pulsed laser beam 104-1 having a horizontal polarization and a second pulsed laser beam 104-2 having a vertical polarization. The polarizing beamsplitter 114 combines the first pulsed laser beam 104-1 and the second pulsed laser beam 104-2 into a colinear beam having orthogonal polarization states separated in a time domain. After the polarizing beamsplitter 114, the first pulsed laser beam 104-1 and the second pulsed laser beam 104-2 maintain the respective horizontal and vertical polarizations within the combined laser beam 108.

The polarization modulator 116 may be positioned in the common beam path and configured to selectively rotate a polarization state of a subset of pulses in the combined laser beam 108. For example, the polarization modulator 116 may selectively rotate the polarization of pulses from the second pulsed laser beam 104-2 by 90 degrees to match the horizontal polarization of pulses from the first pulsed laser beam 104-1. In this way, the polarization modulator 116 modulates a polarization rotation applied to the pulses in synchronization with the pulse generation such that all pulses in the combined laser beam 108 have a common polarization state.

FIG. 2B is a timing diagram depicting the operation of the polarization modulator 116 relative to pulses in the first pulsed laser beam 104-1 and the second pulsed laser beam 104-2, in accordance with one or more embodiments of the present disclosure. The upper plot depicts the combined laser beam 108 as alternating pulses from the first pulsed laser beam 104-1 and the second pulsed laser beam 104-2. The lower plot depicts the timing of polarization rotation applied by the polarization modulator 116. In FIG. 2B, the polarization modulator 116 selectively applies polarization rotation to pulses in the second pulsed laser beam 104-2 while pulses in the first pulsed laser beam 104-1 pass through without polarization rotation.

FIG. 3A is a schematic diagram of a beam combining assembly 106 for combining three pulsed laser beams using a cascaded configuration of polarizing beamsplitters 114 and polarization modulators 116, in accordance with one or more embodiments of the present disclosure.

In FIG. 3A, the beam combining assembly 106 includes a first stage and a second stage. The first stage is substantially the same as depicted in FIGS. 2A-2B and combines a first pulsed laser beam 104-1 with a second pulsed laser beam 104-2. In the first stage, the first pulsed laser beam 104-1 having horizontal polarization and the second pulsed laser beam 104-2 having vertical polarization are combined by a first polarizing beamsplitter 114. A first polarization modulator 116 then selectively rotates the polarization of pulses within the second pulsed laser beam 104-2 to horizontal polarization such that pulses from the first pulsed laser beam 104-1 and the second pulsed laser beam 104-2 have a common polarization state.

In the second stage, a third pulsed laser beam 104-3 having vertical polarization is combined with the output of the first stage by a second polarizing beamsplitter 114. A second polarization modulator 116 then selectively rotates the polarization of pulses within the third pulsed laser beam 104-3 to horizontal polarization, such that all pulses in the combined laser beam 108 have a common polarization state.

This cascaded process may be repeated any number of times to combine any number of pulsed laser beams 104. In FIG. 3A, the components of the first pulsed laser beam 104-1, the second pulsed laser beam 104-2, and the third pulsed laser beam 104-3 are shown as non-overlapping for clarity, but are overlapping in practice.

FIG. 3B is a timing diagram depicting the operation of the polarization modulators 116 relative to pulses in the first pulsed laser beam 104-1, the second pulsed laser beam 104-2, and the third pulsed laser beam 104-3, in accordance with one or more embodiments of the present disclosure.

The upper plot depicts the combined laser beam as interleaved pulses from the first pulsed laser beam 104-1, the second pulsed laser beam 104-2, and the third pulsed laser beam 104-3. The middle plot depicts the timing of polarization rotation applied by the first polarization modulator 116 (stage 1), which selectively applies polarization rotation to pulses in the second pulsed laser beam 104-2 while pulses in the first pulsed laser beam 104-1 and the third pulsed laser beam 104-3 pass through without polarization rotation. The lower plot depicts the timing of polarization rotation applied by the second polarization modulator 116 (stage 2), which selectively applies polarization rotation to pulses in the third pulsed laser beam 104-3 while pulses in the first pulsed laser beam 104-1 and the second pulsed laser beam 104-2 pass through without polarization rotation.

The polarization modulator 116 may include any components suitable for modifying polarization states of select pulses in the combined laser beam 108.

In some embodiments, the polarization modulator 116 includes an electro-optic modulator such as, but not limited to, a Pockels cell. Electro-optic modulators may provide rapid polarization rotation suitable for the kilohertz repetition rates of the lasers 102. For example, a Pockels cell may operate at frequencies of tens of kilohertz or hundreds of kilohertz, which is substantially faster than the pulse repetition rates of the lasers 102 in the kilohertz range.

In some embodiments, the polarization modulator 116 includes one or more waveplates that may be selectively inserted into the path of the combined laser beam 108.

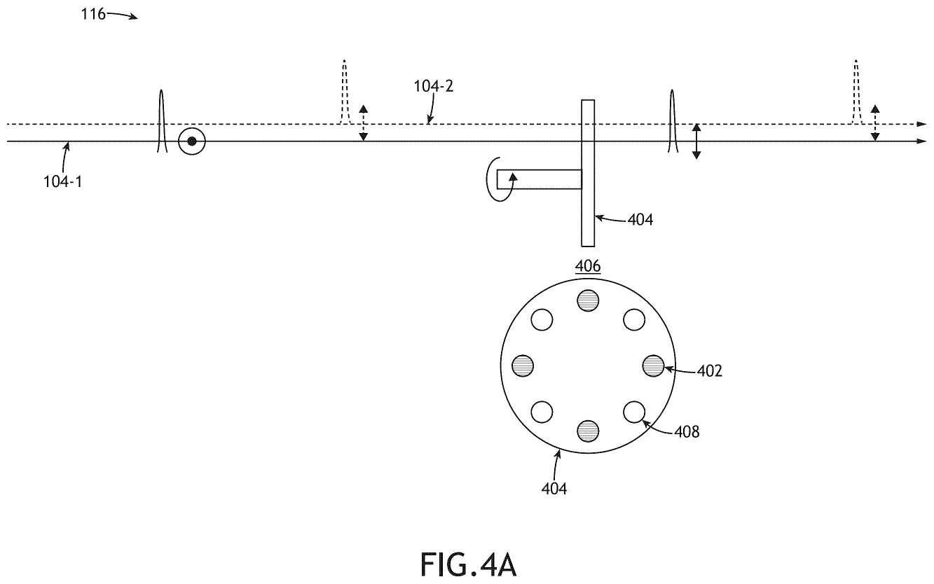

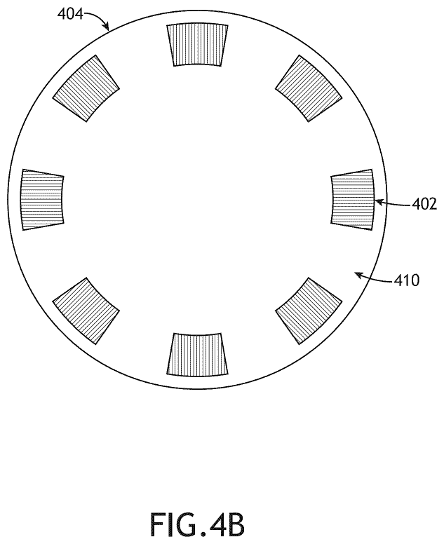

FIG. 4A is a schematic diagram of a polarization modulator 116 utilizing half waveplates 402 arranged on an opaque rotating mount 404, in accordance with one or more embodiments of the present disclosure.

In FIG. 4A, the first pulsed laser beam 104-1 having horizontal polarization and the second pulsed laser beam 104-2 having vertical polarization travel along a common beam path. The polarization modulator 116 includes one or more half waveplates 402 arranged on a rotating mount 404. In this way, the rotating mount 404 may selectively insert the one or more half waveplates 402 into the common beam path in synchronization with the pulse generation.

An inset 406 provides a detailed view of the rotating mount 404. As shown in the inset 406, the rotating mount 404 may include a circular disk with an alternating series of half waveplates 402 and open apertures 408. As the rotating mount 404 rotates in synchronization with the interleaved pulses from the lasers 102, the half waveplates 402 selectively intercept pulses from the first pulsed laser beam 104-1 to rotate the polarization of the pulses from the first pulsed laser beam 104-1 to horizontal polarization. Pulses from the second pulsed laser beam 104-2 may instead pass through the open apertures 408 without polarization rotation.

FIG. 4B is a a schematic diagram of a polarization modulator 116 utilizing half waveplates 402 arranged on a transparent rotating mount 404, in accordance with one or more embodiments of the present disclosure.

In FIG. 4B, the rotating mount 404 comprises a transparent circular disk formed as a transparent substrate 410 with half waveplates 402 arranged alternately around a circumference of the rotating mount 404. In this configuration, the half waveplates 402 are positioned at regular intervals around the perimeter of the rotating mount 404, with regions of the transparent substrate 410 positioned between adjacent half waveplates 402.

The transparent substrate 410 may be formed from any material transparent to the pulsed laser beams 104. For example, the transparent substrate 410 may be formed from a glass such as, but not limited to, fused silica or a borosilicate glass.

The half waveplates 402 may be formed on the transparent substrate 410 using any suitable technique. In some embodiments, the half waveplates 402 may be formed using an etched grating structure on the transparent substrate 410. In some embodiments, the half waveplates 402 may be formed using meta surfaces on the transparent substrate 410. In some embodiments, the half waveplates 402 may be formed using laser induced birefringence in the transparent substrate 410.

In a manner similar to FIG. 4A, the rotating mount 404 may rotate in synchronization with interleaved pulses from the lasers 102 such that the half waveplates 402 may selectively intercept and modify the polarization of pulses from first pulsed laser beam 104-1 to rotate the polarization of those pulses, while pulses from the second pulsed laser beam 104-2 may pass through the transparent substrate 410 regions without polarization rotation.

It is to be understood that FIGS. 4A and 4B and the associated descriptions are provided solely for illustrative purposes and should not be interpreted as limiting the scope of the present disclosure. For example, one or more half waveplates 402 may be mounted on a linear translation stage for selective insertion into the path of the combined laser beam 108.

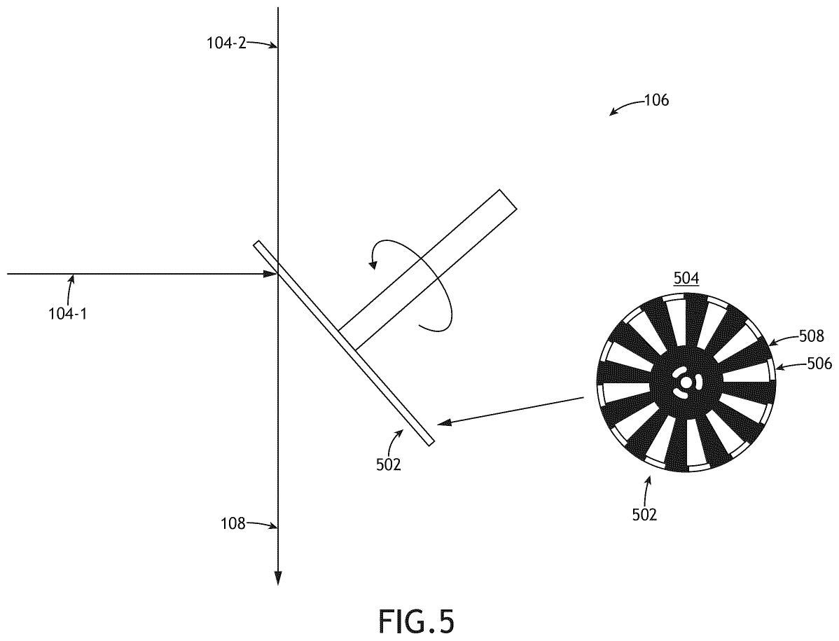

Referring now to FIG. 5, in some embodiments, the beam combining assembly 106 includes one or more components that may combined multiple pulsed laser beam 104 without modifying the respective polarizations.

FIG. 5 is a schematic diagram of a beam combining assembly 106 utilizing a rotating patterned mirror 502 for combining pulsed laser beams from multiple lasers 102, in accordance with one or more embodiments of the present disclosure.

In FIG. 5, a first pulsed laser beam 104-1 traveling along a first path and a second pulsed laser beam 104-2 traveling along a second path are directed toward the rotating patterned mirror 502. The rotating patterned mirror 502 may be positioned at an angle to receive the first pulsed laser beam 104-1 and the second pulsed laser beam 104-2.

An inset 504 provides a detailed view of the rotating patterned mirror 502. As shown in the inset 504, the rotating patterned mirror 502 may include a circular disk having alternating transparent regions 506 and opaque regions 508 arranged around a circumference of the circular disk. The rotating patterned mirror 502 may include a glass substrate having a patterned mirror coating defining the opaque regions 508. In this configuration, the transparent regions 506 may allow transmission of one pulsed laser beam while the opaque regions 508 reflect the other pulsed laser beam.

Rotation of the rotating patterned mirror 502 may be synchronized (e.g,. via the timing controller 110) with the pulse generation of each laser 102 to alternately reflect and transmit the pulsed laser beams from the lasers 102 into the combined laser beam 108. For example, as the rotating patterned mirror 502 rotates in synchronization with the interleaved pulses from the lasers 102, the alternating transparent regions 506 and opaque regions 508 combine the first pulsed laser beam 104-1 and the second pulsed laser beam 104-2 into the combined laser beam 108 along a common beam path.

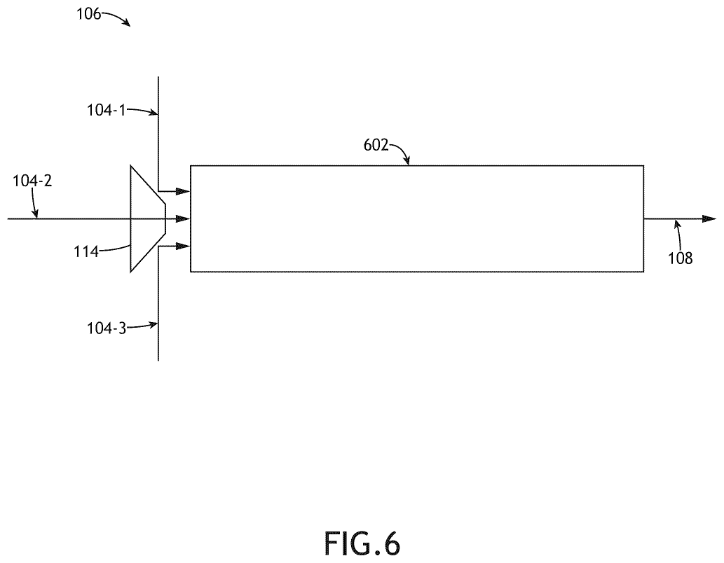

Referring now to FIG. 6, in some embodiments, the beam combining assembly 106 may utilize a light pipe 602 for combining pulsed laser beams from multiple lasers 102.

FIG. 6 is a schematic diagram of a beam combining assembly 106 utilizing the light pipe 602 for combining pulsed laser beams from multiple lasers 102, in accordance with one or more embodiments of the present disclosure.

In FIG. 6, the first pulsed laser beam 104-1, the second pulsed laser beam 104-2, and the third pulsed laser beam 104-3 are directed toward the beamsplitter 114. The beamsplitter 114 combines the first pulsed laser beam 104-1, the second pulsed laser beam 104-2, and the third pulsed laser beam 104-3 and directs the combined beams into the light pipe 602.

The light pipe 602 receives the pulsed laser beams from the lasers 102 and homogenizes the beams along a common beam path to form the combined laser beam 108.

In some embodiments, a light pipe 602 may operate as a homogenizer to increase a spatial uniformity of light. For example, in the configuration shown in FIG. 6, the light pipe 602 may homogenize the combined laser beam 108.

In some embodiments, the light source 100 includes one or more beam homogenizers such as, but not limited to, light pipes configured to homogenize the pulsed laser beam 104 prior to being combined by the beam combining assembly 106. For example, it may be the case that the light from a laser 102 is not fully spatially uniform.

However, it may be the case that a homogenizer such as a light pipe may depolarize light while improving spatial uniformity.

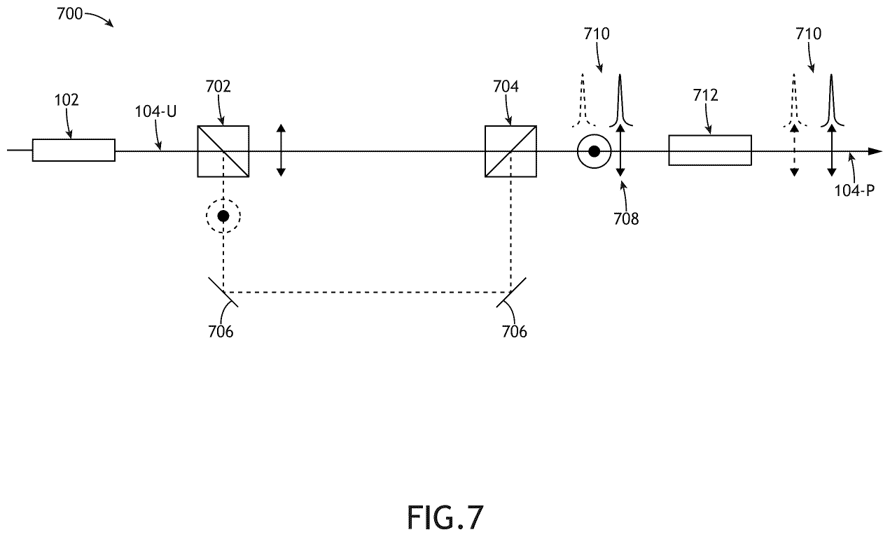

FIG. 7 is a schematic diagram of a polarization recovery assembly 700 configured to receive a depolarized beam and output a polarized beam, in accordance with one or more embodiments of the present disclosure.

In FIG. 7, a laser 102 generates an unpolarized pulsed laser beam 104-U. The unpolarized pulsed laser beam 104-U may result from depolarization caused by a beam homogenizer such as, but not limited to, a light pipe.

In some embodiments, the polarization recovery assembly 700 includes a first polarizing beamsplitter 702 configured to separate the unpolarized pulsed laser beam 104-U into a first component with a first polarization state and a second component with a second polarization state. For example, the first polarizing beamsplitter 702 may separate the unpolarized pulsed laser beam 104-U into a first polarization component having horizontal polarization and a second polarization component having vertical polarization. The polarization recovery assembly 700 may further include a second polarizing beamsplitter 704 to recombine the two components having the different polarization states. In this way, all of the energy from the incident unpolarized pulsed laser beam 104-U is utilized and converted into a polarized pulsed laser beam 104-P.

In some embodiments, the first component having the first polarization state and the second component having the second polarization state travel along different optical path lengths before being recombined into the recombined beam 708. For example, FIG. 7 depicts mirrors 706 to delay the vertically-polarized light relative to the horizontally-polarized light. This configuration may enable polarization synchronization using an additional polarization modulator 712 in a manner similar to that described with respect to FIGS. 2A-3B. For example, the additional polarization modulator 712 may rotate the polarization of the delayed second polarization component by 90 degrees to match the polarization of the first polarization component. In this way, both polarization components in the recombined beam 708 have a common polarization state and exit the polarization recovery assembly 700 as a polarized pulsed laser beam 104-P.

In this configuration, the polarized pulsed laser beam 104-P may include pulse bursts 710 at the pulse repetition rate of the laser 102, where each pulse burst 710 includes a first sub-pulse from the first polarization component and a second sub-pulse from the delayed second polarization component.

The temporal separation between the first sub-pulse and the second sub-pulse within each pulse burst 710 may correspond to the delay introduced by the delay path formed by the mirrors 706. In some embodiments, the delay introduced by the delay path may be selected based on a response time of the additional polarization modulator 712 to allow for the selective modification of pulses within each pulse burst 710. For example, the delay path length may be configured such that the temporal separation between the first sub-pulse and the second sub-pulse is greater than or equal to the switching time of the additional polarization modulator 712.

In some embodiments, the light source 100 includes a beam homogenizer and a polarization recovery assembly 700 for each pulsed laser beam 104 from the lasers 102 prior to the beam combining assembly 106. For example, each laser 102 may have an associated light pipe to homogenize the respective pulsed laser beam 104, followed by a polarization recovery assembly 700 to convert the depolarized output into a polarized pulsed laser beam 104-P having pulse bursts 710 as described with respect to FIG. 7. In this configuration, the combined laser beam 108 may include a series of pulse bursts at the combined repetition rate, where each pulse burst includes a first sub-pulse and a second sub-pulse separated by the temporal delay introduced by the delay path in the respective polarization recovery assembly 700. The pulse bursts from different lasers 102 may be interleaved in the time domain by the timing controller 110, resulting in a combined laser beam 108 having an increased effective pulse rate while maintaining a common polarization state for all pulses.

In some applications, a combined laser beam having pulse bursts may be functionally indistinguishable from a combined laser beam having uniformly spaced pulses. For example, in imaging applications where the image acquisition time is substantially longer than the temporal separation between sub-pulses within a pulse burst, the detector may integrate the light from both sub-pulses within a single acquisition period. In such cases, the pulse bursts may effectively contribute to the image in a manner similar to uniformly spaced pulses, and the temporal structure of the pulse bursts may not affect the resulting image quality or measurement accuracy.

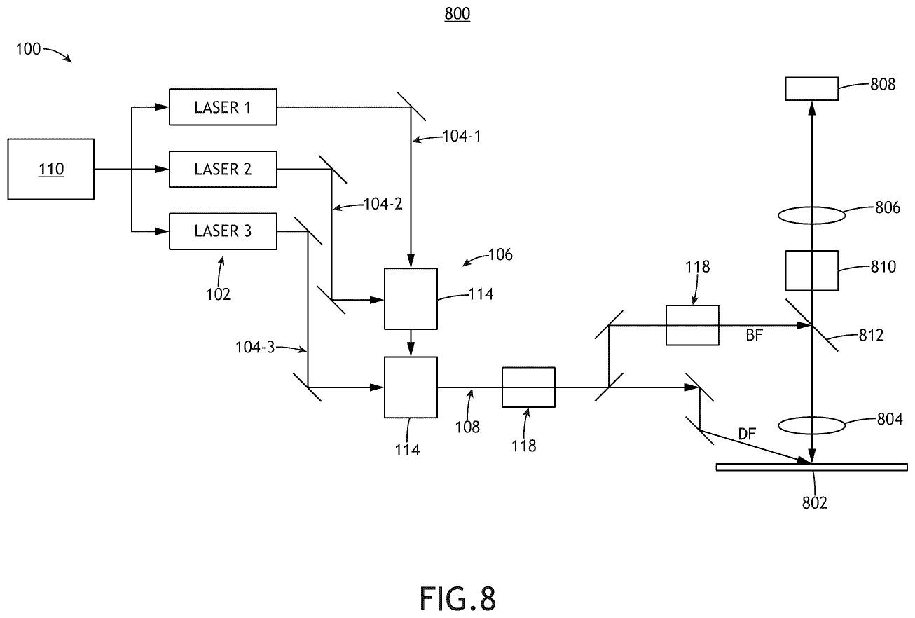

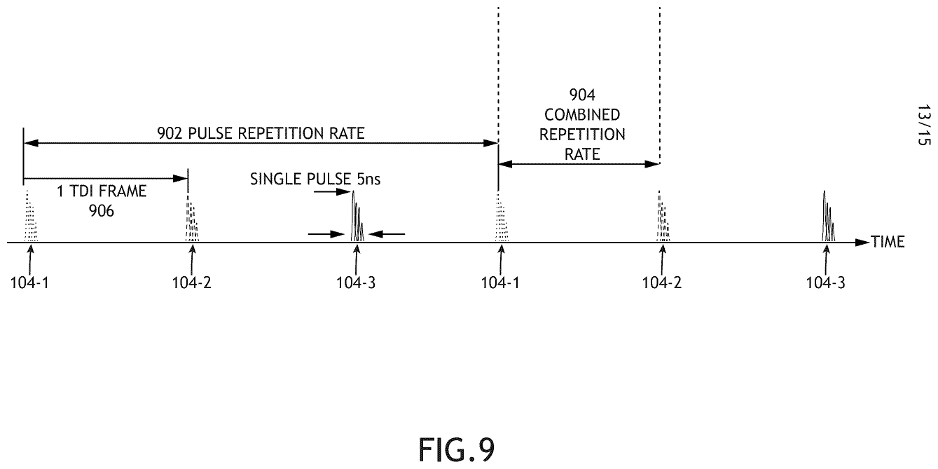

Referring now to FIGS. 8-9, the combined laser source described herein may be incorporated into a sample characterization system for high-speed inspection and metrology applications.

FIG. 8 is a schematic diagram of a sample characterization system 800 incorporating the light source 100, in accordance with one or more embodiments of the present disclosure.

In embodiments, the sample characterization system 800 includes the light source 100 as described with respect to FIGS. 1A-7. As shown in FIG. 8, the light source 100 includes the timing controller 110 communicatively coupled to the lasers 102 (shown here as Laser 1, Laser 2, and Laser 3, but this three-laser source is only an illustration). Each laser 102 generates a pulsed laser beam, including the first pulsed laser beam 104-1, the second pulsed laser beam 104-2, and the third pulsed laser beam 104-3. The pulsed laser beams are directed through the beamsplitters 114 in the beam combining assembly 106 to form the combined laser beam 108. The combined laser beam 108 passes through the beam shaping optics 118, which may include a pulse stretcher configured to temporally stretch pulses in the combined laser beam 108.

In some embodiments, the sample characterization system 800 further includes illumination optics configured to direct the combined laser beam 108 onto a sample 802 and collection optics to image the sample 802 onto a detector 808.

For example, the sample characterization system 800 may include an objective lens 804 to collect light from the sample 802. In some cases, the objective lens 804 is a catadioptric lens that is corrected for the laser spectral linewidth. For example, the objective lens 804 may be corrected for a spectral linewidth of approximately 1-2 nm, which is typical for lasers 102. As shown in FIG. 8, the sample characterization system 800 may further include an imaging lens 806 (e.g., a tube lens) to image the sample 802 to the detector 808.

In some embodiments, the sample characterization system 800 may be configured for multiple imaging modes. For example, FIG. 8 depicts a bright-field (BF) path and a dark-field (DF) path. In a bright-field mode, the combined laser beam 108 may be directed to the sample 802 through the objective lens 804 (e.g., via a beamsplitter 812) so that the objective lens 804 may capture specularly-reflected light. In a dark-field mode, imaging may be based on scattered or diffracted light, where specular reflection is either blocked or the combined laser beam 108 is directed to the sample 802 outside the numerical aperture of the objective lens 804.

The illumination optics and collection optics may generally include any components suitable for manipulating the respective light. For example, the illumination optics and/or collection optics may include, but are not limited to, polarizers, homogenizers, spectral filters, or spatial filters. As shown in FIG. 8, the sample characterization system 800 may include beam shaping optics 118 in the illumination path to manipulate properties of the combined laser beam 108. In some embodiments, the sample characterization system 800 includes polarization optics 810 to control the polarization state of the imaging light, which may be particularly beneficial for, but not limited to, inspection.

The detector 808 may include any type of sensor suitable for receiving the collected light from the sample 802. For example, the detector 808 may include, but is not limited to, a complementary metal-oxide-semiconductor (CMOS) sensor, a charge-coupled device (CCD) sensor, or a time delay integration (TDI) sensor. In some embodiments, the detector 808 includes a TDI sensor, which may be particularly suitable for high-speed scanning applications where the sample 802 is in continuous motion relative to the illumination.

Synchronization of the combined laser beam 108 with a TDI detector 808 are now described in greater detail, in accordance with one or more embodiments of the present disclosure.

FIG. 9 is a timing diagram depicting the relationship between a pulse repetition rate 902, a combined repetition rate 904, and a TDI frame rate 906 during imaging, in accordance with one or more embodiments of the present disclosure.

In FIG. 9, the first pulsed laser beam 104-1, the second pulsed laser beam 104-2, and the third pulsed laser beam 104-3 are shown as interleaved in the time domain. FIG. 9 also depicts the pulse repetition rate 902 associated with individual lasers 102, the combined repetition rate 904, and a TDI frame rate 906. As an illustration, three lasers 102 each operating at 2 kHz may be combined to generate a 6 kHz combined pulse train. In this configuration, the three lasers 102 are synchronized with a time offset of approximately 167 microseconds between successive pulses from different lasers 102. The timing controller 110 may coordinate the pulse generation such that the pulses from the first pulsed laser beam 104-1, the second pulsed laser beam 104-2, and the third pulsed laser beam 104-3 are uniformly distributed in the time domain. By combining and interleaving pulses from multiple lasers 102, the combined repetition rate 904 is greater than the pulse repetition rate 902 of any individual laser 102, enabling higher throughput sample characterization.

In some embodiments, a TDI detector 808 is configured to receive the collected light and operate at a line rate synchronized with motion of the sample 802 as well as the combined laser beam 108. For example, the TDI detector 808 may be configured such that a number of TDI integration lines covers a distance the sample 802 travels between consecutive laser pulses in the combined laser beam 108. In the illustrative example above, the TDI detector 808 may be configured such that the number of TDI integration lines corresponds to the distance traveled by the sample 802 during the 167 microsecond interval between consecutive pulses.

The actual number of TDI integration lines may be determined by the time duration of the stretched pulse even though the integration of the TDI sensor is continuous. The stretched pulse width may be controlled to optimize the number of pixels to be integrated. More integrated pixels may allow more averaging and therefore may improve the uniformity of the image. However, a large number of integrated pixels may blur the image when curvature of the scan path increases towards the center of the sample 802 (e.g., a wafer center). This operating mode may provide various advantages including, but not limited to: improving the imaging non-uniformity caused by sensor response and illumination non-uniformity compared to single frame flash imaging; and enabling the use of a TDI sensor with a large number of integration pixels to accommodate the low repetition rate of the lasers 102 while achieving the same imaging quality as a TDI sensor with a small number of integration pixels for spiral scanning.

In some embodiments, an illumination beam size of the combined laser beam 108 on the sample 802 covers a total number of TDI integration lines in both horizontal and vertical directions. The illumination beam size may also include additional pixels for integration over the stretched pulse width, plus headroom for overfill to accommodate alignment tolerance.

In some embodiments, the TDI detector 808 operates in a TDI scan mode rather than an areal imaging mode. The TDI scan mode may be suitable when the stretched pulse is long enough to cause motion blur in areal imaging mode. In the TDI scan mode, the TDI detector 808 synchronizes charge transfer with the motion of the sample 802, enabling continuous image acquisition without motion blur.

In some embodiments, the TDI detector 808 has a size inversely proportional to the laser repetition rate. For example, the size of the TDI detector 808 may be determined based on a relationship between sensor size, data rate, and laser repetition rate. For example, the size of the TDI detector 808 at a given total data rate may be given by:

$$[ Laser Repetition Rate ] = \frac{Data Rate}{Total Sensor Pixels} . \qquad ( 1 )$$

In some embodiments, the TDI detector 808 has a squared shape, which may provide a minimum optical field diameter to reduce the cost of the objective lens 804.

In some embodiments, the pulses in the combined laser beam 108 are temporally stretched (e.g., with a pulse stretecher). For example, the pulses may be stretched such that each stretched pulse covers multiple TDI integration lines along a scan direction. As a nonlimiting illustration, the pulse stretcher may be configured to stretch each pulse to a duration between 0.1 microseconds and 1 microseconds.

The pulse stretching provided by the beam shaping optics 118 may provide various benefits for the sample characterization system 800. For example, pulse stretching reduces peak power of the laser pulses to reduce laser damage to optics and the sample 802. As another example, pulse stretching may facilitate TDI sensor uniformity by averaging over multiple pixels, which may provide improved uniformity compared to single pulse per frame flash-on-the-fly imaging with area sensors.

In addition to temporally stretching pulses, the pulse stretcher may also reduce spatial coherence of the laser light, which may improve imaging quality by reducing speckle noise. In some embodiments, the laser 102 has a coherence length of approximately 1 mm or less, resulting in residual speckle contrast in the range of 5%-10%. To reduce speckle contrast to below 1%, the pulse stretcher may be configured to provide approximately 100× delayed and re-mixed pulses, requiring a total delay length of approximately 100 mm. This delay length is practical to implement given the short coherence length of lasers 102. In some embodiments, the pulse stretcher includes a total internal reflection (TIR) cavity that provides a 1 ns time delay using approximately 200 mm path length in glass with a refractive index of n=1.5. The achievable stretched pulse width may depend on tolerance of optical losses, which are proportional to the total delay distance. Accordingly, the stretched pulse width may represent a trade-off between usable laser power and pulse duration.

In some embodiments, the sample characterization system 800 is configured for arc scan path imaging. In arc scan path imaging, the sample 802 may be rotated while the illumination beam scans radially, resulting in an arc-shaped scan trajectory. In this configuration, the stretched pulse width may be controlled to integrate over a small number of pixels in the TDI scan direction to minimize image blur near a center of the sample 802 (e.g., a wafer center).

Referring now again to FIG. 8, in some embodiments, the sample characterization system 800 may further include a controller including one or more processors configured to execute program instructions stored in memory (e.g., a memory device). The processors of the controller may then execute program instructions causing the processors to implement any of the various steps described in the present disclosure either directly or indirectly (e.g., by generating control signals to control components of the sample characterization system 800 and/or external components). For example, the processors may generate sample measurements based on data from the detector 808, control the timing controller 110 to synchronize pulse generation, or control the beam shaping optics 118.

The one or more processors of a controller may include any processing element known in the art. In this sense, the one or more processors may include any microprocessor-type device configured to execute algorithms and/or instructions. In some embodiments, the one or more processors may consist of a desktop computer, mainframe computer system, workstation, image computer, parallel processor, or any other computer system (e.g., networked computer) configured to execute a program configured to operate the sample characterization system 800, as described throughout the present disclosure. It is further recognized that the term “processor” may be broadly defined to encompass any device having one or more processing elements, which execute program instructions from a non-transitory memory. Further, the steps described throughout the present disclosure may be carried out by a single controller or, alternatively, multiple controllers. Additionally, the controller may include one or more controllers housed in a common housing or within multiple housings. In this way, any controller or combination of controllers may be separately packaged as a module suitable for integration into sample characterization system 800.

The memory may include any storage medium known in the art suitable for storing program instructions executable by the associated one or more processors. For example, the memory may include a non-transitory memory medium. By way of another example, the memory may include, but is not limited to, a read-only memory, a random-access memory, a magnetic or optical memory device (e.g., disk), a magnetic tape, a solid-state drive and the like. It is further noted that memory may be housed in a common controller housing with the one or more processors. In some embodiments, the memory may be located remotely with respect to the physical location of the one or more processors and controller. For instance, the one or more processors of controller may access a remote memory (e.g., server), accessible through a network (e.g., internet, intranet and the like). Therefore, the above description should not be interpreted as a limitation on the present invention but merely an illustration.

In some embodiments, the sample characterization system 800 is an inspection system and the sample measurements include at least one of identification of defects on the sample 802 or characterization of defects on the sample 802.

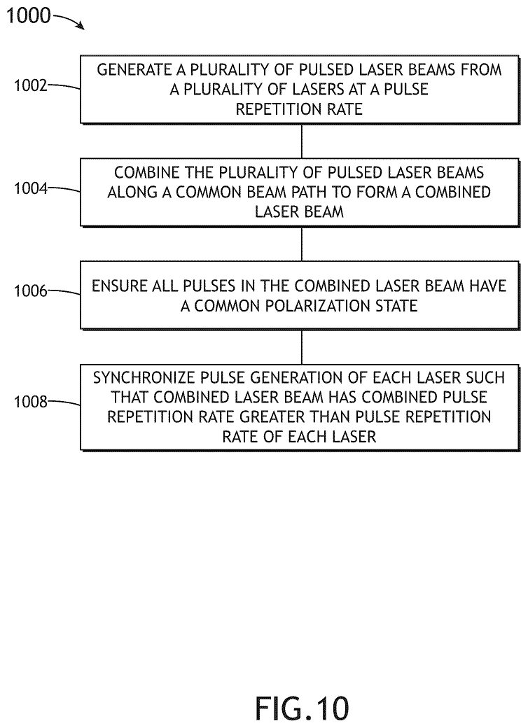

FIG. 10 is a flowchart for a method 1000 for generating a combined laser beam from a plurality of lasers 102 with synchronized pulse generation, in accordance with one or more embodiments of the present disclosure.

In some embodiments, the method 1000 includes a step 1002 of generating multiple pulsed laser beams from multiple lasers, wherein each laser generates a pulsed laser beam at a pulse repetition rate. This step may involve activating the lasers 102 to produce the pulsed laser beams 104. The lasers 102 may be implemented as separate standalone laser units or as multiple laser cavities 120 sharing at least one of a common housing, a common gas supply 124, or a common power supply 122.

In some embodiments, the method 1000 includes a step 1004 of combining the pulsed laser beams along a common beam path to form a combined laser beam having a combined pulse repetition rate greater than the pulse repetition rate of each laser. This step may involve directing the pulsed laser beams 104 from the lasers 102 through the beam combining assembly 106 to form the combined laser beam 108. The beam combining assembly 106 may include various optical configurations for combining the pulsed laser beams 104.

In some embodiments, combining the pulsed laser beams may be achieved through various optical configurations. For example, the pulsed laser beams may be combined using polarizing beam splitters as described with respect to FIGS. 2A-3B, using a rotating patterned mirror 502 as described with respect to FIG. 5, or using a light pipe 602 as described with respect to FIG. 6.

In some embodiments, the method 1000 includes a step 1006 of ensuring all pulses in the combined laser beam have a common polarization state. This step may involve selectively rotating a polarization state of a subset of the laser pulses in synchronization with the pulse generation such that all pulses in the combined laser beam have the common polarization state. For example, the polarization modulator 116 may selectively rotate the polarization of pulses from the second pulsed laser beam 104-2 by 90 degrees to match the horizontal polarization of pulses from the first pulsed laser beam 104-1. The polarization modulator 116 may include an electro-optic modulator such as a Pockels cell, or may include the half waveplates 402 arranged on the rotating mount 404 for selective insertion into the common beam path.

In some embodiments, the method 1000 includes a step 1008 of synchronizing pulse generation of each laser such that the combined laser beam has the combined pulse repetition rate. This step may involve the timing controller 110 coordinating the pulse generation of each laser 102 with controlled time offsets. In some embodiments, synchronizing the pulse generation comprises distributing laser pulses in the combined laser beam uniformly in a time domain. In some embodiments, synchronizing the pulse generation results in pulse bursts at the combined repetition rate, where each pulse burst includes sub-pulses from a polarization recovery assembly as described with respect to FIG. 7.

In some embodiments, the method 1000 further includes recovering polarization of a depolarized beam resulting from homogenizing at least one pulsed laser beam. This polarization recovery may be performed using the polarization recovery assembly 700 as described with respect to FIG. 7. The polarization recovery may include separating the depolarized beam into a first polarization component and a second polarization component using the first polarizing beamsplitter 702, delaying the second polarization component relative to the first polarization component via the delay path formed by the mirrors 706, recombining the first polarization component and the delayed second polarization component into the recombined beam 708 using the second polarizing beamsplitter 704, and rotating a polarization state of one of the first polarization component or the delayed second polarization component using the additional polarization modulator 712 such that the recombined beam 708 is linearly polarized. This polarization recovery technique converts each unpolarized pulse into a pulse burst 710 containing two sub-pulses with a common polarization state, effectively utilizing laser power that would otherwise be lost when polarizing unpolarized laser output from a beam homogenizer.

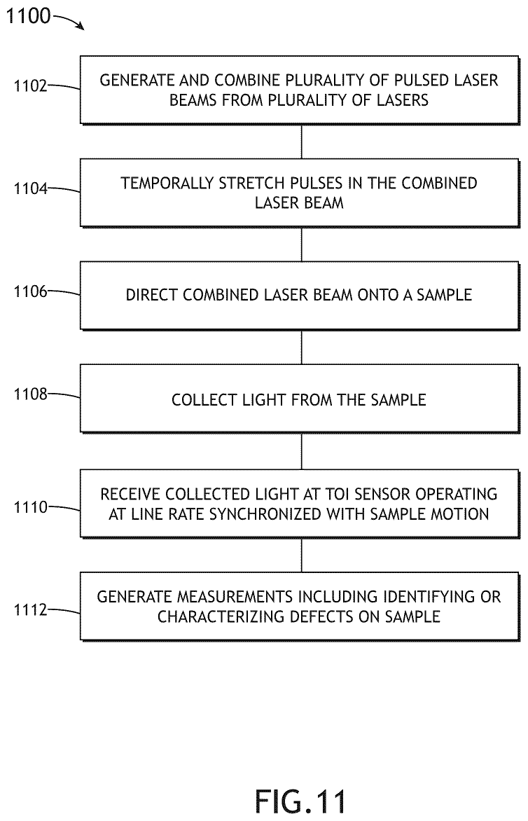

FIG. 11 is a flowchart for a method 1100 for sample characterization using combined laser sources, in accordance with one or more embodiments of the present disclosure.

In some embodiments, the method 1100 includes a step 1102 of generating and combining multiple pulsed laser beams from multiple lasers along a common beam path to form a combined laser beam having a combined pulse repetition rate greater than the pulse repetition rate of each individual laser, wherein all pulses in the combined laser beam have a common polarization state. This step may involve activating the lasers 102 to produce the pulsed laser beams 104 and directing the pulsed laser beams 104 through the beam combining assembly 106 to form the combined laser beam 108. The timing controller 110 may coordinate the pulse generation of each laser 102 with controlled time offsets such that laser pulses in the combined laser beam 108 are distributed uniformly in a time domain. The beam combining assembly 106 may include polarizing beamsplitters 114 and polarization modulators 116 to combine the pulsed laser beams 104 while ensuring that all pulses in the combined laser beam 108 have the common polarization state.

In some embodiments, the method 1100 includes a step 1104 of temporally stretching pulses in the combined laser beam. This step may involve passing the combined laser beam 108 through the beam shaping optics 118, which may include a pulse stretcher configured to temporally stretch pulses in the combined laser beam 108.

The temporal stretching reduces peak power of the laser pulses to mitigate laser damage to optics and the sample 802. The temporal stretching may also enable each stretched pulse to cover multiple TDI integration lines along a scan direction, which may improve sensor uniformity by averaging over multiple pixels and reduce speckle noise. For example, the pulse stretcher may stretch each pulse to a duration between 0.1 microseconds and 1 microsecond.

In some embodiments, the method 1100 includes a step 1106 of directing the combined laser beam onto a sample. This step may involve directing the combined laser beam 108 through illumination optics to illuminate the sample 802. The illumination optics may include the objective lens 804 and the polarization optics 810 to control the illumination characteristics on the sample 802. The combined laser beam 108 may illuminate the sample 802 in a bright-field mode, a dark-field mode, or other imaging configurations.

In some embodiments, the method 1100 includes a step 1108 of collecting light from the sample. This step may involve collecting light from the sample 802 using collection optics such as the objective lens 804 and the imaging lens 806. The collected light may include scattered light, reflected light, or transmitted light depending on the characterization mode. For example, in a dark-field mode, the collected light may include light scattered or diffracted by features or defects on the sample 802. In a bright-field mode, the collected light may include specularly reflected light from the sample 802.

In some embodiments, the method 1100 includes a step 1110 of receiving the collected light at a time delay integration (TDI) sensor operating at a line rate synchronized with motion of the sample. This step may involve the detector 808 receiving the collected light from the sample 802, where the detector 808 includes a TDI sensor configured to operate at a line rate synchronized with motion of the sample 802. The synchronization may ensure that a number of TDI integration lines covers a distance the sample 802 travels between consecutive laser pulses in the combined laser beam 108. The TDI sensor may operate in a TDI scan mode, synchronizing charge transfer with the motion of the sample 802 to enable continuous image acquisition without motion blur.

In some embodiments, the method 1100 includes a step 1112 of generating one or more measurements based on data from the TDI sensor. This step may involve a controller including one or more processors analyzing data from the detector 808 to generate sample measurements. In some embodiments, generating the one or more measurements comprises at least one of identifying defects on the sample 802 or characterizing defects on the sample 802. For example, the controller may process the image data from the TDI sensor to detect defects, classify defect types, measure defect sizes, or determine defect locations on the sample 802. The measurements may be used for quality control, process monitoring, or yield improvement in semiconductor manufacturing applications.

All of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random-access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes.

In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A light source comprising:
a plurality of lasers, wherein each laser of the plurality of lasers is configured to generate a pulsed laser beam at a pulse repetition rate;
a beam combining assembly including one or more beam combining optics configured to direct the pulsed laser beams from the plurality of lasers along a common beam path to form a combined laser beam, wherein all pulses in the combined laser beam have a common polarization state; and
a timing controller communicatively coupled to the plurality of lasers, the timing controller configured to synchronize pulse generation of each laser of the plurality of lasers such that the combined laser beam has a combined pulse repetition rate greater than the pulse repetition rate of any of the plurality of lasers.

2. The light source of claim 1, wherein the beam combining assembly comprises:
one or more polarizing beam splitters configured to combine the pulsed laser beams from the plurality of lasers into a colinear beam having orthogonal polarization states separated in a time domain; and
a polarization modulator in the common beam path, the polarization modulator configured to selectively rotate a polarization state of a subset of pulses in the combined laser beam by modulating a polarization rotation applied to the pulses in synchronization with the pulse generation such that all pulses in the combined laser beam have the common polarization state.

3. The light source of claim 2, wherein the polarization modulator comprises an electro-optic modulator including a Pockels cell.

4. The light source of claim 2, wherein the polarization modulator comprises one or more half waveplates arranged on a rotating mount, the rotating mount configured to selectively insert the one or more half waveplates into the common beam path in synchronization with the pulse generation.

5. The light source of claim 2, wherein the timing controller is communicatively coupled to the polarization modulator and configured to synchronize operation of the polarization modulator with the pulse generation of each laser of the plurality of lasers.

6. The light source of claim 1, wherein the beam combining assembly comprises a rotating patterned mirror having alternating transparent regions and opaque regions, wherein the rotating patterned mirror comprises a glass substrate having a patterned mirror coating defining the opaque regions, and wherein rotation of the rotating patterned mirror is synchronized with the pulse generation of each laser of the plurality of lasers to alternately reflect and transmit the pulsed laser beams from the plurality of lasers into the combined laser beam.

7. The light source of claim 1, wherein the timing controller is configured to synchronize the pulse generation such that laser pulses in the combined laser beam are distributed uniformly in a time domain.

8. The light source of claim 1, further comprising a beam homogenizer configured to homogenize at least one pulsed laser beam of the pulsed laser beams from the plurality of lasers.

9. The light source of claim 8, wherein the beam homogenizer comprises a light pipe.

10. The light source of claim 8, further comprising a polarization recovery assembly configured to receive a depolarized beam from the beam homogenizer and output a polarized beam, the polarization recovery assembly comprising:
a first polarizing beam splitter configured to separate the depolarized beam into a first polarization component and a second polarization component;
a delay path configured to delay the second polarization component relative to the first polarization component;
a second polarizing beam splitter configured to recombine the first polarization component and the delayed second polarization component into a recombined beam; and
a polarization rotator configured to rotate a polarization state of one of the first polarization component or the delayed second polarization component such that the recombined beam is linearly polarized.

11. The light source of claim 10, wherein the recombined beam comprises pulse bursts at the combined repetition rate, each pulse burst including a first sub-pulse from the first polarization component and a second sub-pulse from the delayed second polarization component.

12. The light source of claim 1, wherein the one or more beam combining optics comprise a light pipe configured to receive the pulsed laser beams from the plurality of lasers.

13. The light source of claim 1, wherein the plurality of lasers comprises a plurality of laser cavities sharing at least one of a common housing, a common gas supply, or a common power supply.

14. The light source of claim 1, wherein the plurality of lasers comprises excimer lasers.

15. A sample characterization system comprising:
a light source including:
a plurality of lasers, wherein each laser of the plurality of lasers is configured to generate a pulsed laser beam at a pulse repetition rate;
a beam combining assembly including one or more beam combining optics configured to direct the pulsed laser beams from the plurality of lasers along a common beam path to form a combined laser beam, wherein all pulses in the combined laser beam have a common polarization state;
a timing controller communicatively coupled to the plurality of lasers, the timing controller configured to synchronize pulse generation of each laser of the plurality of lasers such that the combined laser beam has a combined pulse repetition rate greater than the pulse repetition rate of any of the plurality of lasers;
illumination optics configured to direct the combined laser beam onto a sample;
collection optics configured to collect light from the sample; and
a time delay integration (TDI) sensor configured to receive the collected light, wherein the TDI sensor is configured to operate at a line rate synchronized with motion of the sample such that a number of TDI integration lines covers a distance the sample travels between consecutive laser pulses in the combined laser beam.

16. The sample characterization system of claim 15, further comprising a pulse stretcher configured to temporally stretch pulses in the combined laser beam such that each stretched pulse covers multiple TDI integration lines along a scan direction.

17. The sample characterization system of claim 16, wherein the pulse stretcher is configured to stretch each pulse to a duration between 0.1 microseconds and 1 microsecond.

18. The sample characterization system of claim 15, wherein an illumination beam size of the combined laser beam on the sample covers a total number of TDI integration lines in both horizontal and vertical directions.

19. The sample characterization system of claim 15, further comprising a controller including one or more processors configured to generate sample measurements based on data from the TDI sensor.

20. The sample characterization system of claim 19, wherein the sample characterization system is an inspection system and the sample measurements comprise at least one of identification of defects on the sample or characterization of defects on the sample.

21. The sample characterization system of claim 15, wherein the plurality of lasers comprises excimer lasers.

22. A method comprising:
generating a plurality of pulsed laser beams from a plurality of lasers, wherein each laser of the plurality of lasers generates a pulsed laser beam at a pulse repetition rate;
combining the plurality of pulsed laser beams along a common beam path to form a combined laser beam having a combined pulse repetition rate greater than the pulse repetition rate of each laser of the plurality of lasers, wherein all pulses in the combined laser beam have a common polarization state; and
synchronizing pulse generation of each laser of the plurality of lasers such that the combined laser beam has the combined pulse repetition rate.

23. The method of claim 22, wherein synchronizing the pulse generation comprises distributing laser pulses in the combined laser beam uniformly in a time domain.

24. The method of claim 22, wherein combining the plurality of pulsed laser beams comprises:
directing the plurality of pulsed laser beams through one or more polarizing beam splitters to form a colinear beam having orthogonal polarization states separated in a time domain; and
selectively rotating a polarization state of a subset of the laser pulses in synchronization with the pulse generation such that all pulses in the combined laser beam have the common polarization state.

25. The method of claim 22, wherein combining the plurality of pulsed laser beams comprises:
directing the plurality of pulsed laser beams onto a rotating patterned mirror having alternating transparent regions and opaque regions, wherein rotation of the rotating patterned mirror is synchronized with the pulse generation to alternately reflect and transmit the pulsed laser beams into the combined laser beam.

26. The method of claim 22, further comprising homogenizing at least one pulsed laser beam of the plurality of pulsed laser beams.

27. The method of claim 26, further comprising recovering polarization of a depolarized beam from the homogenizing by:
separating the depolarized beam into a first polarization component and a second polarization component;
delaying the second polarization component relative to the first polarization component;
recombining the first polarization component and the delayed second polarization component into a recombined beam; and
rotating a polarization state of one of the first polarization component or the delayed second polarization component such that the recombined beam is linearly polarized.

28. The method of claim 22, further comprising temporally stretching pulses in the combined laser beam.

29. The method of claim 22, further comprising:
directing the combined laser beam onto a sample;
collecting light from the sample;
receiving the collected light at a time delay integration (TDI) sensor operating at a line rate synchronized with motion of the sample; and
generating one or more measurements based on data from the TDI sensor.

30. The method of claim 29, wherein generating the one or more measurements comprises at least one of identifying defects on the sample or characterizing defects on the sample.

31. The method of claim 22, wherein the plurality of lasers comprises excimer lasers.
